(19) United States
(12) Patent Application Publication
(10) Pub. No.: US 2024/0176250 A1
(43) Pub. Date: May 30, 2024

(54) DETERMINATION METHOD, EXPOSURE METHOD, METHOD OF MANUFACTURING ARTICLE, INFORMATION PROCESSING APPARATUS, AND EXPOSURE APPARATUS

(71) Applicant: CANON KABUSHIKI KAISHA, Tokyo (JP)

(72) Inventor: ATSUSHI TAKAGI, Tochigi (JP)

(21) Appl. No.: 18/516,825

(22) Filed: Nov. 21, 2023

(30) Foreign Application Priority Data
Nov. 29, 2022 (JP) 2022-190571

(51) Int. Cl. G03F 7/00

(52) U.S. Cl. CPC G03F 7/70358; G03F 7/7055; G03F 7/706

(57) ABSTRACT

The present disclosure provides a determination method of determining a first driving profile of a substrate in scanning exposure of transferring a pattern image of an original to a shot region on the substrate by scan-driving the substrate with respect to slit-shaped light, including obtaining information representing a distortion in an underlaying pattern on the shot region, calculating, for each of a plurality of positions in a non-scanning direction intersecting a scanning direction of the substrate, based on the information obtained in the obtaining, a second driving profile of the substrate for overlaying the pattern image of the original on the underlaying pattern in the scanning exposure, and generating the first driving profile from the second driving profiles each calculated in the calculating for each of the plurality of positions in the non-scanning direction.

### BACKGROUND

### Field of the Disclosure

The present disclosure generally relates to aspects of lithography.

### Description of the Related Art

As a lithography apparatus used in a step of manufacturing a semiconductor device or the like, there is known an exposure apparatus that performs so-called scanning exposure of transferring a pattern of an original onto a substrate by exposing the substrate while scan-driving the substrate with respect to slit-shaped light having passed through the original. In an underlying pattern formed on the substrate (shot region), a distortion may have occurred by a series of processing operations. Therefore, the exposure apparatus is required to accurately overlay (transfer) the pattern image of the original on the underlying pattern on the substrate (shot region) where the distortion has occurred. Japanese Patent Laid-Open No. 2009-88142 describes a technique of determining a stage moving profile of scanning exposure (a driving profile of a substrate) based on data of a distortion and the width (slit width) of slit-shaped light in a scanning direction.

In the underlying pattern on the substrate (shot region), the tendency of the distortion may be different among a plurality of positions in a non-scanning direction intersecting the scanning direction. In this case, if the stage moving profile of scanning exposure is not determined in consideration of the tendency of the distortion at each position in the non-scanning direction, a portion where the overlay accuracy between the underlying pattern and the pattern image of the original does not satisfy a predetermined range (required specification) may be generated in the shot region.

### SUMMARY

The present disclosure provides, for example, a technique advantageous in overlay accuracy in scanning exposure of a substrate.

According to one aspect of the present disclosure, there is provided a determination method of determining a first driving profile of a substrate in scanning exposure of transferring a pattern image of an original to a shot region on the substrate by scan-driving the substrate with respect to slit-shaped light, comprising: obtaining information representing a distortion in an underlaying pattern on the shot region; calculating, for each of a plurality of positions in a non-scanning direction intersecting a scanning direction of the substrate, based on the information obtained in the obtaining, a second driving profile of the substrate for overlaying the pattern image of the original on the underlaying pattern in the scanning exposure; and generating the first driving profile from the second driving profiles each calculated in the calculating for each of the plurality of positions in the non-scanning direction.

Further features of the present disclosure will become apparent from the following description of embodiments with reference to the attached drawings.

### BRIEF DESCRIPTION OF THE DRAWINGS

FIG. 1 is a view showing an example of the arrangement of an exposure apparatus;

FIG. 2A is a view showing an example of a distortion in an underlying pattern on a shot region;

FIG. 2B is a view showing an example of the distortion in the underlying pattern on the shot region;

FIG. 3 is a view for explaining the width (slit width) of slit-shaped light;

FIGS. 4A and 4B are views showing exposure results at a plurality of points with different slit widths, respectively; and

FIG. 5 is a flowchart illustrating a determination method of determining a scan-driving profile.

### DESCRIPTION OF THE EMBODIMENTS

Hereinafter, embodiments will be described in detail with reference to the attached drawings. Note, the following embodiments are not intended to limit the scope of the claimed disclosure. Multiple features are described in the embodiments, but limitation is not made a disclosure that requires all such features, and multiple such features may be combined as appropriate. Furthermore, in the attached drawings, the same reference numerals are given to the same or similar configurations, and redundant description thereof is omitted.

In the specification and the accompanying drawings, directions will be indicated on an XYZ coordinate system in which a direction parallel to the optical axis of a projection optical system is defined as the Z direction, that is, an XYZ coordinate system in which the image plane of the projection optical system is defined as the X-Y plane. Directions parallel to the X-axis, the Y-axis, and the Z-axis of the XYZ coordinate system are the X direction, the Y direction, and the Z direction, respectively. A rotation about the X-axis, a rotation about the Y-axis, and a rotation about the Z-axis are OX, OY, and OZ, respectively. Control or driving (movement) concerning the X-axis, the Y-axis, and the Z-axis means control or driving (movement) concerning a direction parallel to the X-axis, a direction parallel to the Y-axis, and a direction parallel to the Z-axis, respectively. In addition, control or driving concerning the OX-axis, the OY-axis, and the OZ-axis means control or driving concerning a rotation about an axis parallel to the X-axis, a rotation about an axis parallel to the Y-axis, and a rotation about an axis parallel to the Z-axis, respectively.

An exposure apparatus used to manufacture a semiconductor element such as a semiconductor memory, a logic circuit, or an image device, forms, on a substrate (wafer), by a projection optical system, an image of a circuit pattern formed on an original (reticle or mask), thereby transferring the pattern onto the substrate. The exposure apparatus is required to project and transfer the pattern image of the original onto the substrate with higher resolving power along with miniaturization and an increase in density of an integrated circuit. The smallest critical dimension (resolution) at which the exposure apparatus can transfer the pattern image onto the substrate is proportional to the wavelength of light used for exposure, and is inversely proportional to the numerical aperture (NA) of the projection optical system. Therefore, the resolution is improved as the wavelength is decreased. Thus, in recent years, the exposure apparatus has used a light source such as an i-ray lamp (a wavelength of about 365 nm), a KrF excimer laser of a shorter wavelength (a wavelength of about 248 nm), or an ArF excimer laser (a wavelength of about 193 nm). Furthermore, immersion exposure in which a liquid such as water is filled in a portion between the substrate and the projection optical system or double exposure (Double Patterning: DP) in which an etching process is added between a plurality of times of exposure is proposed and implemented. In addition, exposure using Extreme Ultraviolet light (EUV light) with a wavelength of 13 to 14 nm is adopted, and an exposure apparatus using this is applied to mass production.

Since it is predicted that difficulty of microfabrication will increase and the cost of the processing apparatus will increase, a technique of increasing a memory capacity by stacking the circuit structure of a device without relying on miniaturization have also been considered and realized. In particular, a memory device such as a NAND memory has recently, been significantly improved in memory capacity by stacking, and deposition and a resist process coping with this increase the thickness. A memory obtained by stacking NAND memories is called a 3D-NAND, and in this device, a memory is formed for each layer and leading wirings are connected in a staircase shape, thereby requiring a stepwise processing process. After the series of processing operations, a distortion in the pattern (underlying pattern) formed on the substrate may become conspicuous. Therefore, when performing overlay exposure of overlaying the pattern image of the original on the underlying pattern of the substrate and transferring it, the exposure apparatus desirably considers the distortion in the underlying pattern.

As an exposure apparatus, there is known a scanning exposure apparatus (scanner) that performs scanning exposure of a substrate by relatively scan-driving an original and the substrate with respect to slit-shaped light (exposure light) having a rectangular or circular sectional shape. The scanning exposure apparatus can control scan-driving of the substrate in scanning exposure, thereby accurately overlaying the pattern image of the original on the underlying pattern on the substrate (shot region) in which a distortion has occurred. However, in the underlying pattern on the substrate (shot region), the tendency of the distortion may be different among a plurality of positions in the non-scanning direction intersecting (for example, orthogonal to) the scanning direction. In this case, since the degree of freedom of control of scan-driving of the substrate is smaller in the non-scanning direction than in the scanning direction, a portion where the overlay accuracy between the underlying pattern and the pattern image of the original does not satisfy a predetermined range (required specification) may be generated in the shot region. Therefore, it is desirable to determine the driving profile of the substrate in scanning exposure in consideration of the difference in tendency of the distortion among the plurality of positions in the non-scanning direction.

Furthermore, the integrated exposure amount (integrated exposure dose) of the substrate is defined by the width (the length in the scanning direction) of the slit-shaped light. More specifically, the integrated exposure amount at a given point on the substrate is defined by a period (exposure time) in which the slit-shaped light passes through the point and the moving average value of the intensity of the slit-shaped light in the period. If, for example, a fog is generated on the optical element of the projection optical system, the scanning exposure apparatus adjusts the width of the slit-shaped light at each position by a slit adjustment mechanism provided in an illumination optical system so that the integrated exposure amount at each of the plurality of positions in the non-scanning direction becomes equal to a target exposure amount. This can reduce unevenness of the integrated exposure amount in the non-scanning direction. However, if the width of the slit-shaped light is changed, the moving average effect of the intensity of the slit-shaped light changes, and thus the sharpness of the pattern image transferred to the substrate (shot region) changes, and the position (transfer position) of the pattern image transferred onto the substrate can accordingly change. Then, if the width of the slit-shaped light is different among the plurality of positions in the non-scanning direction, the transfer accuracy, that is, the overlay accuracy of the pattern image is different among the plurality of positions in the non-scanning direction. Therefore, it is desirable to determine the driving profile of the substrate in scanning exposure in consideration of the difference in width of the slit-shaped light among the plurality of positions in the non-scanning direction.

### First Embodiment

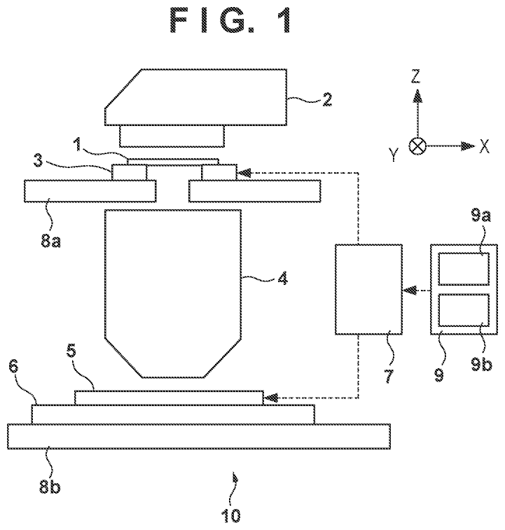

The first embodiment according to the present disclosure will be described. FIG. 1 is a view showing an example of the arrangement of an exposure apparatus 10 according to this embodiment. The exposure apparatus 10 is an exposure apparatus using a step-and-scan method, that performs scanning exposure of a substrate by relatively scan-driving an original 1 and a substrate 5 with respect to slit-shaped light (exposure light) having a rectangular or circular sectional shape. This exposure apparatus 10 is also called a scanning exposure apparatus or a scanner. Note that the Y direction is the scanning direction and the X direction is the non-scanning direction in the following description.

As shown in FIG. 1, the exposure apparatus 10 can include an illumination optical system 2, an original stage 3, a projection optical system 4, a substrate stage 6, and a control unit 7. The control unit 7 is formed by, for example, a computer including a processor such as a Central Processing Unit (CPU) and a storage unit such as a memory, and controls scanning exposure of the substrate 5 by comprehensively controlling the respective units of the exposure apparatus 10. The control unit 7 is connected to each component of the exposure apparatus 10, and can control each component in accordance with a program.

The illumination optical system 2 generates slit-shaped light (exposure light) using light emitted from a light source (not shown), and illuminates the original 1 with the slit-shaped light. The illumination optical system 2 can include, for example, a slit defining member and a slit adjustment mechanism. The slit defining member includes a plurality of blades that partially shields the light from the light source, and defines, by the plurality of blades, a slit for generating slit-shaped light (exposure light) having a rectangular or circular sectional shape. The slit adjustment mechanism includes an actuator that drives the blades of the slit defining member, and adjusts, by the actuator, the shape of the slit to change the width (the length in the scanning direction) of the slit-shaped light.

The original stage 3 is configured to be movable on a stage base 8a while holding the original 1, and scan-drives the original 1 in the scanning direction (Y direction) in scanning exposure. On the original 1, a circuit pattern to be transferred to each of a plurality of shot regions on the substrate 5 is formed. Furthermore, the substrate stage 6 is configured to be movable on a stage base 8b while holding the substrate 5, and scan-drives the substrate 5 in the scanning direction (Y direction) in scanning exposure. The original 1 and the substrate 5 are arranged at optically conjugate positions (the object plane and the image plane of the projection optical system 4) with the projection optical system 4 intervening therebetween. The projection optical system 4 includes a plurality of optical elements (for example, a lens and a mirror), and projects the pattern image of the original 1 illuminated with the slit-shaped light from the illumination optical system 2 onto the substrate 5 at a predetermined projection magnification.

In scanning exposure of the substrate 5, the exposure apparatus 10 having the above arrangement relatively scan-drives the original 1 and the substrate 5 by the original stage 3 and the substrate stage 6 in the scanning direction (Y direction) at a speed ratio according to the projection magnification of the projection optical system 4. This can transfer the pattern image of the original 1 onto the shot region on the substrate 5. Then, such scanning exposure is repeated sequentially for the plurality of shot regions on the substrate 5.

Furthermore, the exposure apparatus 10 of this embodiment includes an information processing apparatus 9. The information processing apparatus 9 is formed by, for example, a computer including a processing unit (processor) 9a such as a CPU and a storage unit 9b such as a memory, and determines (generates) a driving profile for scan-driving the substrate 5 in scanning exposure. The information processing apparatus 9 is formed as a component of the exposure apparatus 10 in this embodiment but may be formed separately from the exposure apparatus 10 (that is, as an external apparatus of the exposure apparatus 10). Furthermore, the information processing apparatus 9 may be formed as part of the control unit 7, or may be formed separately from the control unit 7.

As described above, in the underlying pattern formed on the shot region on the substrate 5, the tendency of the distortion may be different among the plurality of positions in the non-scanning direction. For example, in a recent semiconductor device such as a 3D-NAND memory or a CMOS sensor, since a complicated process step is performed, the generation amount of a distortion may be different in the non-scanning direction in the underlying pattern formed on one shot region on the substrate 5.

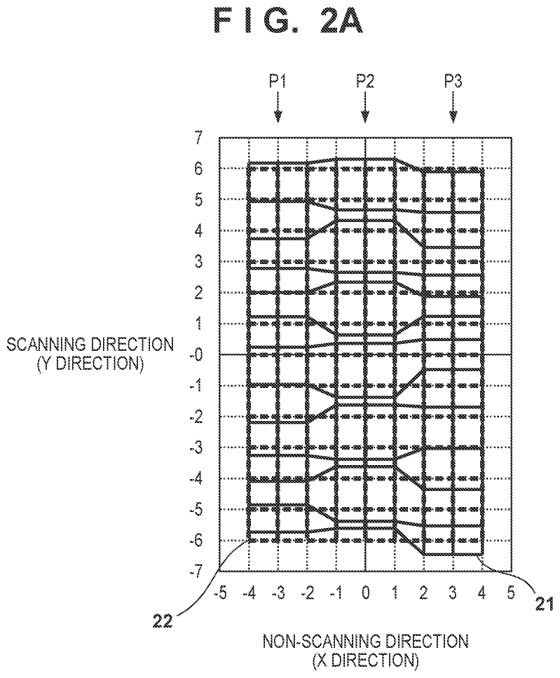

FIGS. 2A and 2B show an example of a distortion in the underlaying pattern on one shot region. FIG. 2A shows an example of the distortion map of the underlaying pattern on one shot region. In FIG. 2A, the underlaying pattern on the shot region is represented by a lattice 21 in the X and Y directions, and the distortion in the underlaying pattern is represented as a deviation (to be sometimes simply referred to as a deviation hereinafter) with respect to an ideal lattice 22 in the X and Y directions. FIG. 2B shows the deviation distribution in the scanning direction (Y direction) in the distortion map shown in FIG. 2A. FIG. 2B shows the deviation distribution in the scanning direction with respect to positions P1 to P3 in the non-scanning direction. In the underlaying pattern on the shot region shown in FIGS. 2A and 2B, the tendency of the distortion is different between the plurality of positions P1 and P2 in the non-scanning direction. Therefore, if the tendency of the distortion that is different between the plurality of positions P1 and P2 is not considered, a portion where the overlay accuracy between the underlying pattern and the pattern image of the original 1 locally, largely decreases may be generated in scanning exposure of the shot region. In other words, a portion where an overlay error between the underlying pattern and the pattern image of the original 1 is locally large may be generated. Therefore, it is desirable to determine the driving profile of the substrate in scanning exposure so that the overlay accuracy in the entire shot region satisfies the predetermined range (required specification).

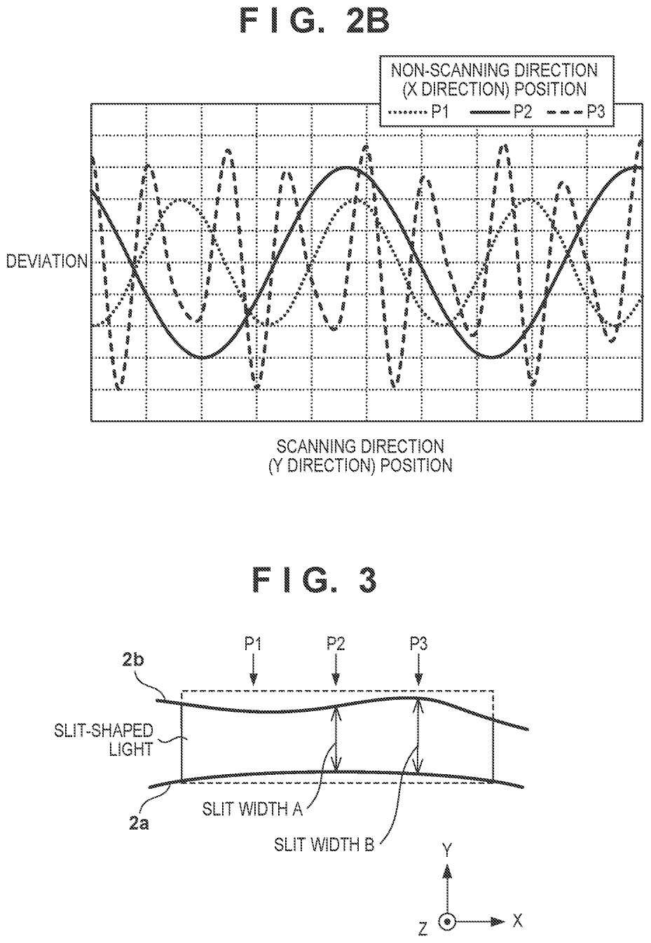

As described above, if the width (the length in the scanning direction) of the slit-shaped light is different among the plurality of positions in the non-scanning direction, the transfer accuracy, that is, the overlay accuracy of the pattern image can be different among the plurality of positions in the non-scanning direction. FIG. 3 is a view for explaining the width (slit width) of the slit-shaped light emitted to the substrate 5, and shows a slit defining member (a fixed blade 2a and a variable blade 2b) of the illumination optical system 2. For example, the slit adjustment mechanism of the illumination optical system 2 adjusts the width (slit width) of the slit-shaped light at each of the positions P1 to P3 by driving the variable blade 2b at each of the positions P1 to P3 in the non-scanning direction.

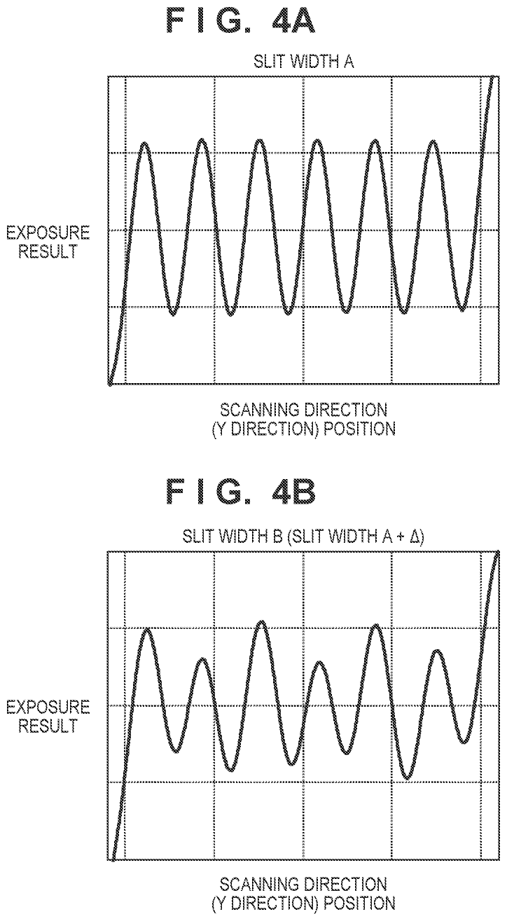

FIG. 4A shows an exposure result at the position P2 with a slit width A, and FIG. 4B shows an exposure result at the position P3 with a slit width B that is larger than the slit width A by a value A. The exposure result is a result (transfer position) of transferring the pattern image of the original 1 onto the shot region so as to be overlaid on the underlaying pattern on the shot region in which a distortion that periodically changes in the scanning direction (Y direction) occurs. As shown in FIGS. 4A and 4B, it is apparent that if the slit width changes by the value A, the exposure result accordingly changes. That is, if the slit width is different among the plurality of positions P1 to P3 in the non-scanning direction, the transfer accuracy, that is, the overlay accuracy of the pattern image is different among the plurality of positions P1 to P3 due to the moving average result of the intensity of the slit-shaped light.

To cope with this, in this embodiment, for each of the plurality of positions in the non-scanning direction, the second driving profile of the substrate 5 is calculated to overlay the pattern image of the original 1 on the underlaying pattern on the shot region on the substrate 5 in scanning exposure. Then, one scan-driving profile (to be sometimes referred to as the first driving profile hereinafter) for driving the substrate 5 in scanning exposure is generated from the second driving profiles calculated for the respective positions in the non-scanning direction. Note that the second driving profile may be understood as the ideal driving profile of the substrate 5 for overlaying the pattern image of the original 1 on the underlaying pattern on the shot region on the substrate 5 in scanning exposure with respect to each of the plurality of positions in the non-scanning direction.

In this example, each of the first driving profile and the second driving profile is a profile for defining a data string of the driving amount of the substrate 5 (substrate stage 6) in scanning exposure. The driving amount can include at least one of the scanning speed of the substrate 5 (substrate stage 6), a position in the scanning direction, a height (a position in the Z direction), and an inclination (rotations around about the X-axis, the Y-axis, and the Z-axis). Furthermore, if the driving profile of the substrate 5 in scanning exposure is preset, each of the first driving profile and the second driving profile may be understood as a correction value string (correction profile) for correcting (adjusting) the preset driving profile.

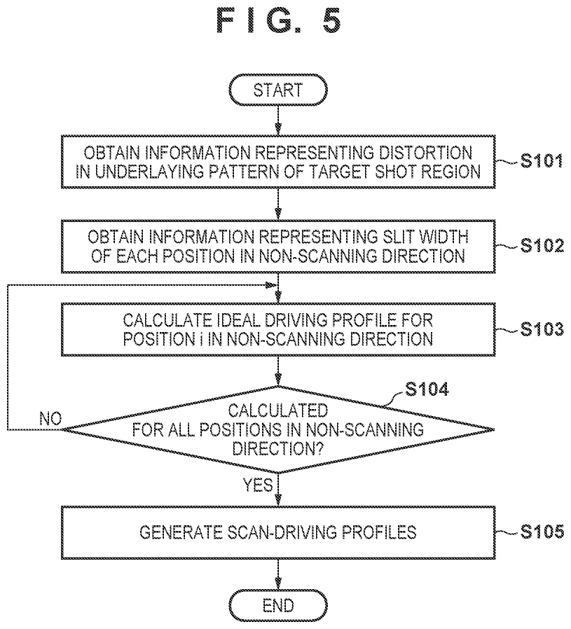

FIG. 5 is a flowchart illustrating a determination method of determining (generating) a scan-driving profile (first driving profile). The flowchart shown in FIG. 5 can be executed by the processing unit 9a of the information processing apparatus 9.

In step S101, the processing unit 9a obtains information (first information) representing a distortion in the underlaying pattern with respect to a shot region (to be sometimes referred to as a target shot region hereinafter) to undergo scanning exposure among the plurality of shot regions on the substrate 5. The distortion in the underlaying pattern on the target shot region can be measured in advance by a measurement apparatus provided inside or outside the exposure apparatus 10. For example, the measurement apparatus can measure the distortion in the underlaying pattern by detecting each of the positions of a plurality of marks provided in the underlaying pattern on the target shot region.

In step S102, the processing unit 9a obtains information (second information) representing the slit width at each of the plurality of positions in the non-scanning direction. For example, the processing unit 9a can obtain the information representing the slit width at each position in the non-scanning direction based on the driving amount of the slit defining member (blades) by the slit adjustment mechanism of the illumination optical system 2. However, the present disclosure is not limited to this. If a detection unit that detects the slit width at each position in the non-scanning direction is provided in the exposure apparatus 10, the processing unit 9a may obtain the information representing the slit width at each position in the non-scanning direction based on the detection result of the detection unit. For example, the detection unit may include a sensor configured to detect the intensity distribution of the slit-shaped light emitted from the illumination optical system 2 or the projection optical system 4, and may be configured to detect the slit width at each position in the non-scanning direction based on the intensity distribution of the slit-shaped light.

In step S103, the processing unit 9a calculates the second driving profile of the substrate 5 for overlaying the pattern image of the original 1 on the underlaying pattern on the shot region in scanning exposure with respect to one position i among the plurality of positions in the non-scanning direction. In this embodiment, the number of the plurality of positions in the non-scanning direction is set to N, and “i” represents the number (i=1 to N) of the position in the non-scanning direction. More specifically, the processing unit 9a obtains (extracts or selects) a distortion at the position i in the non-scanning direction from the information (information representing the distortion in the underlaying pattern) obtained in step S101. Furthermore, the processing unit 9a obtains a slit width at the position i in the non-scanning direction from the information (information representing the slit width at each of the plurality of positions in the non-scanning direction) obtained in step S102. Then, based on the distortion and the slit width obtained with respect to the position i in the non-scanning direction, the processing unit 9a calculates the second driving profile for scan-driving the substrate 5 so as to overlay the pattern image of the original 1 on the underlaying pattern at the position i. The second driving profile can be calculated for each position in the non-scanning direction using, for example, linear programming described in Japanese Patent Laid-Open No. 2009-88142.

In step S104, the processing unit 9a determines whether the second driving profile is calculated for each of the plurality of positions in the non-scanning direction. If there is a position in the non-scanning direction for which the second driving profile has not been calculated, the process returns to step S103, and the position is set as the position i to calculate the second driving profile for the position i. On the other hand, if the second driving profile is calculated for all the plurality of positions in the non-scanning direction, the process advances to step S105. In this case, the second driving profiles (that is, N second driving profiles) are calculated for the N positions in the non-scanning direction.

In step S105, the processing unit 9a generates one first driving profile from the plurality (N) of second driving profiles calculated in steps S103 and S104. In this embodiment, the processing unit 9a can generate one first driving profile by averaging the N second driving profiles. More specifically, the processing unit 9a can calculate the average value of the N second driving profiles (driving amounts) for each position in the scanning direction, and arrays the average values in the scanning direction, thereby generating one first driving profile. In this example, the processing unit 9a may calculate the representative value of the N second driving profiles (driving amounts) for each position in the scanning direction, and array the representative values in the scanning direction, thereby generating one first driving profile. As the representative value, a median, a mode, or the like can be used, instead of the average value.

Steps S101 to S105 described above can be executed for each of the plurality of shot regions on the substrate, thereby generating the first driving profile for each of the plurality of shot regions. The first driving profile generated for each of the plurality of shot regions can be stored in the storage unit 9b of the information processing apparatus 9, and used by the control unit 7 to perform scanning exposure. More specifically, the control unit 7 obtains, from the information processing apparatus 9 (storage unit 9b), the first driving profile generated for the target shot region to undergo scanning exposure. Then, it is possible to execute scanning exposure of the target shot region while controlling scan-driving of the substrate 5 (substrate stage 6) in accordance with the obtained first driving profile.

As described above, in this embodiment, the second driving profile is calculated for each of the plurality of positions in the non-scanning direction, and one first driving profile is generated from the second driving profiles calculated for the plurality of positions. By using the thus generated first driving profile, it is possible to control scan-driving of the substrate 5 so that the overlay accuracy in the entire shot region satisfies the predetermined range (required specification) in scanning exposure of the shot region. The determination method of determining the first driving profile of the substrate 5 (substrate stage 6) has been explained in this embodiment, but the first driving profile of the original 1 (original stage 3) may be determined in accordance with the determination method. However, since the original 1 and the substrate 5 are scanned (driven) in synchronism with each other, if the first driving profile of the substrate 5 is determined, the first driving profile of the original can accordingly, uniquely be determined.

### Second Embodiment

The second embodiment according to the present disclosure will be described. This embodiment basically inherits the first embodiment and can comply with the first embodiment except matters mentioned below.

This embodiment will describe an example in which a processing unit 9a weights a second driving profile for each position in the non-scanning direction in step S105 of the flowchart shown in FIG. 5. More specifically, the processing unit 9a weights the second driving profile for each position in the non-scanning direction, and generates one first driving profile for each position in the scanning direction by calculating the representative value of the weighted second driving profiles (driving amounts). This can generate the first driving profile to reduce an overlay error in a more important portion in the target shot region. The weighting may be determined by obtaining, in advance, an overlay target of a chip region arranged in the non-scanning direction in the shot region. Furthermore, in a case where the tendency of a distortion is different for each shot region on a substrate 5, the weighting may be determined to improve the overlay error in a specific shot region.

In an example, the processing unit 9a can obtain information (third information) representing the degree of importance of the overlay accuracy at each position in the non-scanning direction, and weight the second driving profile for each position in the non-scanning direction. The information can be input by the user via a user interface. In this case, the processing unit 9a can weight the second driving profile so that the weight is larger as the degree of importance is higher. Furthermore, the processing unit 9a may weight the second driving profile for each position in the non-scanning direction in accordance with the distance between each position in the non-scanning direction and the barycenter (center) of the substrate 5. In this case, the processing unit 9a can weight the second driving profile so that the weight is larger as the distance between each position in the non-scanning direction and the barycenter of the substrate 5 is smaller or the weight is larger as the distance is larger. Furthermore, the processing unit 9a may weight the second driving profile for each position in the non-scanning direction in accordance with the distance between each position in the non-scanning direction and the barycenter (center) of the shot region. In this case, the processing unit 9a can weight the second driving profile so that the weight is larger as the distance between each position in the non-scanning direction and the barycenter of the shot region is smaller or the weight is larger as the distance is larger.

### Third Embodiment

The third embodiment according to the present disclosure will be described. This embodiment basically inherits the first embodiment and can comply with the first embodiment except matters mentioned below. Furthermore, in this embodiment, the second embodiment may be applied.

A slit width at each position in the non-scanning direction can be adjusted appropriately (with time) in accordance with the intensity of light emitted from an illumination optical system 2 or a projection optical system 4. For example, if a fog is generated on the entire optical element of the illumination optical system 2 or the projection optical system 4 or a part of the optical element, the fog can decrease the intensity of the light. Therefore, the slit width at each position in the non-scanning direction is adjusted so that an integrated exposure amount at each position in the non-scanning direction becomes equal to a target exposure amount. In this case, as described above, since the moving average effect of the intensity of the slit-shaped light changes, the sharpness of a pattern image to be transferred to a substrate (shot region) changes, and the position (transfer position) of the pattern image to be transferred onto the substrate can accordingly change. Therefore, if the slit width is adjusted (changed), a processing unit 9a can determine (update) the first driving profile by executing the above-described determination method (steps S101 to S105). By using the thus determined (updated) first driving profile, it is possible to control scan-driving of a substrate 5 so that the overlay accuracy in the entire shot region satisfies the predetermined range (required specification) in scanning exposure of the shot region.

### Embodiment of Method of Manufacturing Article

A method of manufacturing an article according to the embodiment of the present disclosure is suitable for manufacturing, for example, an article, for example, a microdevice such as a semiconductor device or an element having a fine structure. The method of manufacturing an article according to the embodiment includes an exposure step of exposing a substrate using the above-described exposure apparatus (exposure method), a processing step of processing the substrate having been exposed in the exposure step, and a manufacturing step of manufacturing an article from the substrate having been processed in the processing step. The manufacturing method also includes other known steps (for example, oxidation, deposition, vapor deposition, doping, planarization, etching, resist removal, dicing, bonding, and packaging). The method of manufacturing an article according to the embodiment is advantageous in at least one of the performance, quality, productivity, and production cost of the article, as compared to conventional methods.

### OTHER EMBODIMENTS

Embodiment(s) of the present disclosure can also be realized by a computer of a system or apparatus that reads out and executes computer executable instructions (e.g., one or more programs) recorded on a storage medium (which may also be referred to more fully as a ‘non-transitory computer-readable storage medium’) to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like.

While the present disclosure has been described with reference to embodiments, it is to be understood that the disclosure is not limited to the disclosed embodiments. The scope of the following claims is to be accorded the broadest interpretation so as to encompass all such modifications and equivalent structures and functions.

This application claims the benefit of priority from Japanese Patent Application No. 2022-190571 filed on Nov. 29, 2022, which is hereby incorporated by reference herein in its entirety.

What is claimed is:

1. A determination method of determining a first driving profile of a substrate in scanning exposure of transferring a pattern image of an original to a shot region on the substrate by scan-driving the substrate with respect to slit-shaped light, comprising:
obtaining information representing a distortion in an underlaying pattern on the shot region;
calculating, for each of a plurality of positions in a non-scanning direction intersecting a scanning direction of the substrate, based on the information obtained in the obtaining, a second driving profile of the substrate for overlaying the pattern image of the original on the underlaying pattern in the scanning exposure; and
generating the first driving profile from the second driving profiles each calculated in the calculating for each of the plurality of positions in the non-scanning direction.

2. The determination method according to claim 1, wherein
in the obtaining, second information representing a width of the slit-shaped light in the scanning direction is obtained for each of the plurality of positions in the non-scanning direction, and
in the calculating, the second driving profile is calculated for each of the plurality of positions in the non-scanning direction further based on the second information obtained in the obtaining.

3. The determination method according to claim 2, wherein in a case where the width of the slit-shaped light is changed, the first driving profile is determined by executing the calculating and the generating.

4. The determination method according to claim 1, wherein in the generating, the first driving profile is generated by calculating a representative value based on the second driving profiles for each position in the scanning direction.

5. The determination method according to claim 1, wherein in the generating, the second driving profile is weighted for each of the plurality of positions in the non-scanning direction, and the first driving profile is generated by calculating a representative value based on the weighted second driving profiles for each position in the scanning direction.

6. The determination method according to claim 5, wherein
in the obtaining, third information representing a degree of importance of overlay accuracy for each of the plurality of positions in the non-scanning direction is obtained, and
in the generating, the second driving profile for each of the plurality of positions in the non-scanning direction is weighted based on the third information obtained in the obtaining.

7. The determination method according to claim 5, wherein in the generating, the second driving profile is weighted for each of the plurality of positions in the non-scanning direction in accordance with a distance between each of the plurality of positions in the non-scanning direction and a barycenter of the substrate.

8. The determination method according to claim 5, wherein in the generating, the second driving profile is weighted for each of the plurality of positions in the non-scanning direction in accordance with a distance between each of the plurality of positions in the non-scanning direction and a barycenter of the shot region.

9. An exposure method of performing scanning exposure of transferring a pattern image of an original to a shot region on a substrate by scan-driving the substrate with respect to slit-shaped light, comprising:
determining a first driving profile of the substrate in the scanning exposure using a determination method; and
performing the scanning exposure while scan-driving the substrate in accordance with the first driving profile,
wherein the determination method comprises:
obtaining information representing a distortion in an underlaying pattern on the shot region;
calculating, for each of a plurality of positions in a non-scanning direction intersecting a scanning direction of the substrate, based on the information obtained in the obtaining, a second driving profile of the substrate for overlaying the pattern image of the original on the underlaying pattern in the scanning exposure; and
generating the first driving profile from the second driving profiles each calculated in the calculating for each of the plurality of positions in the non-scanning direction.

10. A method of manufacturing an article, the method comprising:
exposing a substrate by using an exposure method;
processing the exposed substrate; and
manufacturing the article from the processed substrate,
wherein the exposure method is a method of performing scanning exposure of transferring a pattern image of an original to a shot region on the substrate by scan-driving the substrate with respect to slit-shaped light, and comprises:
determining a first driving profile of the substrate in the scanning exposure using a determination method; and
performing the scanning exposure while scan-driving the substrate in accordance with the first driving profile, and
wherein the determination method comprises:
obtaining information representing a distortion in an underlaying pattern on the shot region;
calculating, for each of a plurality of positions in a non-scanning direction intersecting a scanning direction of the substrate, based on the information obtained in the obtaining, a second driving profile of the substrate for overlaying the pattern image of the original on the underlaying pattern in the scanning exposure; and
generating the first driving profile from the second driving profiles each calculated in the calculating for each of the plurality of positions in the non-scanning direction.

11. A non-transitory computer-readable storage medium storing a program for causing a computer to execute a determination method according to claim 1.

12. An information processing apparatus for determining a first driving profile of a substrate in scanning exposure of transferring a pattern image of an original to a shot region on the substrate by scan-driving the substrate with respect to slit-shaped light,
the apparatus executing:
obtaining information representing a distortion in an underlaying pattern on the shot region;
calculating, for each of a plurality of positions in a non-scanning direction intersecting a scanning direction of the substrate, based on the information obtained in the obtaining, a second driving profile of the substrate for overlaying the pattern image of the original on the underlaying pattern in the scanning exposure; and
generating the first driving profile from the second driving profiles each calculated in the calculating for each of the plurality of positions in the non-scanning direction.

13. An exposure apparatus for performing scanning exposure of a substrate, comprising:
a stage configured to hold and drive the substrate; and
a control unit configured to control the scanning exposure so as to expose a shot region on the substrate while scan-driving the substrate by the stage with respect to slit-shaped light,
wherein the control unit controls the stage to scan-drive the substrate in accordance with a first driving profile determined by an information processing apparatus defined in claim 12 in the scanning exposure.
